(19) United States
(12) Patent Application Publication
(10) Pub. No.: US 2018/0076347 A1
(43) Pub. Date: Mar. 15, 2018

(54) SOLAR CELL MODULE MANUFACTURING DEVICE AND SOLAR CELL MODULE MANUFACTURING METHOD

(71) Applicant: PANASONIC INTELLECTUAL PROPERTY MANAGEMENT CO., LTD., Osaka (JP)

(72) Inventors: Satoshi Suzuki, Osaka (JP); Takahiro Mishima, Osaka (JP); Masakatsu Muraki, Osaka (JP)

(73) Assignee: PANASONIC INTELLECTUAL PROPERTY MANAGEMENT CO., LTD., Osaka (JP)

(21) Appl. No.: 15/807,708

(22) Filed: Nov. 9, 2017

Related U.S. Application Data
(63) Continuation of application No. PCT/JP2016/002092, filed on Apr. 19, 2016.

(30) Foreign Application Priority Data
May 13, 2015 (JP) 2015-098392

(51) Int. Cl. H01L 31/048; H01L 21/67; B32B 37/06; B32B 17/06

(52) U.S. Cl. CPC H01L 31/048; H01L 21/67115; H01L 31/05; B32B 37/06; B32B 17/06; H01L 21/67126

(57) ABSTRACT

According to one embodiment of the present invention, a solar cell module manufacturing device is provided with: a laminating device for manufacturing a laminated body; and a light source unit, which preferentially heats a solar cell by irradiating the laminated body with light, and which indirectly heats a sealing material by means of a temperature increase of the solar cell. The light source unit has: a plurality of light sources that are disposed on a base material; a light collecting member; a translucent plate; and a cooling device, which is disposed between the base material and the translucent plate, and which flows cooling air in the horizontal direction along a main surface of the translucent plate.

### TECHNICAL FIELD

The present disclosure relates to a solar cell module manufacturing device and a solar cell module manufacturing method.

### BACKGROUND ART

In general, a solar cell module has a structure in which a string of solar cells formed by connecting a plurality of solar cells to each other with conductive wires is sandwiched between two protection members, and a sealing material is filled between the respective protection members. For example, Patent Literature 1 discloses a solar cell module manufacturing method in which a thermocrosslinkable resin sheet is applied as the sealing material. The manufacturing method has a step of pressure bonding a laminated body by heating through irradiation with a specific light wherein the laminated body is formed by sequentially laminating solar cells, thermocrosslinkable resin sheets, and protection members.

### CITATION LIST

### Patent Literature

Patent Literature 1: Japanese Patent Laid-Open Publication No. 2008-117926

### SUMMARY OF INVENTION

### Technical Problem

When a laminated body composed of solar cells, sealing materials and protection members is irradiated with light, improvement in the productivity by increasing the light irradiation intensity to the laminated body is demanded. However, the increase of the light irradiation intensity causes a problem that the heat generation in the light source unit is increased. In other words, it is an important technical problem that the light source unit is efficiently cooled, and that a high light irradiation intensity to the laminated body is secured.

### Solution to Problem

A solar cell module manufacturing device as an aspect of the present disclosure has: a laminating device for preparing a laminated body by superposing, heating and pressure bonding solar cells, sealing materials and protection members; and a light source unit irradiating the laminated body with light to preferentially heat the solar cells and thus indirectly heat the sealing materials through the temperature increase of the solar cells, wherein the light source unit includes a base material; a plurality of light sources disposed on the base material, each outputting light having a maximum peak wavelength of 1500 nm or less; light collecting members disposed on the optical paths of the light beams output from the light sources and collecting the aforementioned light beams; a translucent plate disposed on the optical paths of the light beams emitted from the light collecting members; and a cooling device allowing cooling air to flow in the horizontal direction along the main surface of the translucent plate, between the base material and the translucent plate.

A solar cell module manufacturing method as an aspect of the present disclosure is a solar cell module manufacturing method using the above-described manufacturing device, wherein the manufacturing method includes: a first step of preparing a laminated body by superposing, and heating and pressure bonding solar cells, sealing materials and protection members; and a second step of indirectly heating the sealing materials through the temperature increase of the solar cells caused by irradiating the laminated body with light to preferentially heat the solar cells of the laminated body.

### Advantageous Effects of Invention

According to the solar cell module manufacturing device of the present disclosure, it is possible to efficiently cool the light source unit, and to secure a high light irradiation intensity to the laminated body.

### BRIEF DESCRIPTION OF DRAWINGS

FIG. 1 is a sectional view of a solar cell module as an example of embodiments.

FIG. 2 is a view showing a solar cell module manufacturing device as an example of the embodiments.

FIG. 3 is a plan view of a light source unit as an example of the embodiments.

FIG. 4 is a sectional view along the line AA in FIG. 3.

FIG. 5(A) is a view showing the flow of cooling air and 5(B) a view showing the heat distribution in the light source unit of FIG. 3.

FIG. 6 is a view showing a light irradiation part (a heating furnace, light source unit) as an example of the embodiments.

FIG. 7 is a plan view of a light source unit as another example of the embodiments.

FIG. 8(A) is a view showing the flow of cooling air and 8(B) a view showing the heat distribution in the light source unit of FIG. 7.

FIG. 9(A) is a view showing the flow of cooling air and 9(B) a view showing the heat distribution in the light source unit as another example of the embodiments.

FIG. 10(A) is a view showing the flow of cooling air and 10(B) a view showing the heat distribution in the light source unit as another example of the embodiments.

FIG. 11(A) is a view showing the flow of cooling air and 11(B) a view showing the heat distribution in the light source unit as another example of the embodiments.

FIG. 12 is a sectional view of a light source unit shown as a reference example.

### DESCRIPTION OF EMBODIMENTS

The solar cell module manufacturing device of the present disclosure includes a light source unit irradiating the laminated body with light to preferentially heat the solar cells and thus indirectly heat the sealing materials through the temperature increase of the solar cells. When the adhesion strength between the solar cells and the sealing material is weak, detachment occurs in the interface between the solar cells and the sealing material, and a problem such as exterior appearance failure or insulation reduction is liable to be caused. Accordingly, the manufacturing process of the solar cell module of the present disclosure includes a light irradiation step in order to improve the adhesion strength between the solar cells and the sealing material. When the whole sealing material is heated and the temperature of the sealing material becomes too high, bubbles are generated due to the volatile component in the sealing material, and exterior appearance failure, insulation reduction or the like sometimes occur to a significant extent. The present inventors have discovered that the adhesion strength between the solar cells and the sealing material is improved by heating the solar cells preferentially to the sealing material, without generating bubbles in the sealing material.

In the solar cell module manufacturing device of the present disclosure, the cooling device installed in the light source unit efficiently cools the light source unit. Accordingly, for example, the output power of the light source can be increased, and the number of the light sources arranged in a unit area (area density) can be increased. In other words, according to the solar cell module manufacturing device of the present disclosure, a high intensity light irradiation can be carried out to the laminated body while the light source unit is being prevented from being in an overheated state. Thus, for example, a high intensity light irradiation can be continuously performed, and accordingly the productivity of a solar cell module is improved.

In the present description, the description “approximately **” is intended to mean, for example, in the case of “approximately the same number,” of course the case of being perfectly the same number, but also the case of being regarded as substantially the same number.

Hereinafter, with reference to the accompanying drawings, an example of the embodiments is described in detail.

The drawings referred to in the description of the embodiments are schematically drawn, and the dimensional proportions or the like of the constituent elements depicted in the drawings are sometimes different from those of the actual constituent elements or the like. Specific dimensional proportions or the like should be determined in consideration of the following descriptions.

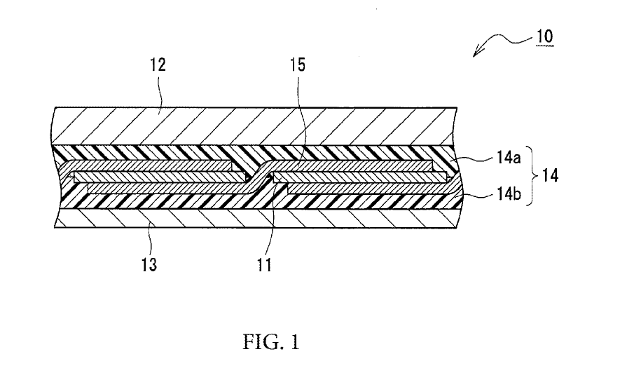

FIG. 1 is a sectional view of the solar cell module 10 as an example of the embodiments.

The solar cell module 10 includes a plurality of solar cells 11, a first protection member 12 provided on the light receiving surface side of the solar cells 11, and a second protection member 13 provided on the rear surface side of the solar cells 11. The plurality of the solar cells 11 are sandwiched by the first protection member 12 and the second protection member 13, and are sealed with a sealing material 14 filled between the protection members. The solar cell module 10 has a plurality of strings, each formed, for example, by connecting the adjacent solar cells 11 to each other with conductive wires 15. The string is a unit formed of a plurality of solar cells 11 arranged so as to form a line and serially connected to each other with the conductive wires 15.

The “light receiving surface” of each of the solar cell module 10 and the solar cell 11 means the surface on which sunlight is mainly incident (more than 50% to 100%), and the “rear surface” means the surface opposite to the light receiving surface. The terms light receiving surface and rear surface, are also used for constituent elements, such as protection members, other than the solar cells 11.

The solar cell 11 has a photoelectric conversion part to produce carriers by receiving sunlight. In the photoelectric conversion part, a light receiving surface electrode is formed on the light receiving surface, and a rear surface electrode is formed on the rear surface (neither of these is shown). The rear surface electrode is preferably formed so as to have a larger area than the area of the light receiving surface electrode. However, the structure of the solar cell 11 is not particularly limited. For example, the solar cell 11 may also have a structure in which an electrode is formed only on the rear surface of the photoelectric conversion part.

The photoelectric conversion part has a semiconductor substrate such as a semiconductor substrate made of crystalline silicon (c-Si), gallium arsenide (GaAs), or indium phosphide (InP), an amorphous semiconductor layer formed on the substrate, and a transparent conductive layer formed on the amorphous semiconductor layer. Specific examples of the photoelectric conversion part include a structure in which on the light receiving surface of an n-type monocrystal silicon substrate, an i-type amorphous silicon layer, a p-type amorphous silicon layer, and a transparent conductive layer are sequentially formed, and on the rear surface, an i-type amorphous silicon layer, an n-type amorphous silicon layer and a transparent conductive layer are sequentially formed. The transparent conductive layers are each preferably constituted with a transparent conductive oxide formed by doping, for example, tin (Sn) or antimony (Sb) in a metal oxide such as indium oxide (In₂O₃) or zinc oxide (ZnO).

The electrodes are each constituted with, for example, a plurality of finger members and a plurality of bus bar members. The finger members are each a fine wire-shaped electrode formed over a wide range on the transparent conductive layer, the bus bar members are the electrodes to collect the carriers from the finger members, and the conductive wires 15 are fixed onto the bus bar members, respectively. The conductive wires 15 are each bent between the adjacent solar cells 11 in the thickness direction of the solar cell module 10, in such a way that the conductive wires are each fixed, with an adhesive or the like, to the light receiving surface of one of the adjacent solar cells 11 and the rear surface of the other of the adjacent solar cells 11.

For the first protection member 12, a member having translucency, such as a glass plate or a resin sheet, can be used. Among these, a glass plate is preferably used from the viewpoint of fire resistance, durability or the like. The thickness of the glass plate is not particularly limited, but is preferably approximately 2 mm to 6 mm. For the second protection member 13, the same transparent member as the first protection member 12 or an opaque member may be used. For the second protection member 13, for example, a resin sheet is preferably used. From the viewpoint of decreasing the moisture permeability, a metal layer such as an aluminum layer or an inorganic compound layer such as a silica layer may also be formed on the resin sheet. The thickness of the resin sheet is not particularly limited, but is preferably approximately 100 μm to 300 μm.

The sealing material 14 is preferably constituted with a first sealing material 14a provided between the solar cells 11 and the first protection member 12, and a second sealing material 14b provided between the solar cells 11 and the second protection member 13. As will be described later in detail, the solar cell module 10 is manufactured by passing through a laminating step using the sheet-shaped sealing materials 14a and 14b (hereinafter, sometimes referred to as “the sealing material sheets 14a and 14b”). The thickness of each of the sealing materials 14a and 14b is not particularly limited, but is preferably approximately 100 μm to 1000 μm.

The constituent material of the sealing material 14 includes a resin that can be applied in the laminating step as the main component (more than 50% by mass), and includes that resin in a content of preferably 80% by mass or more and more preferably 90% by mass or more. The sealing material 14 may also include, in addition to the resin, various additives such as an antioxidant and an ultraviolet absorber, and the sealing material 14b may also include, in addition to the resin, various additives such as a pigment (for example, titanium oxide). The sealing material 14 includes preferably at least a coupling agent.

Examples of the resin suitable as the main component of the sealing material 14 may include an olefin-based resin (such as polyethylene, polypropylene, or a random or block copolymer between ethylene and another α-olefin) obtained by polymerizing at least one olefin selected from α-olefins having 2 to 20 carbon atoms, an ester-based resin (such as a polycondensation product between a polyol and a polycarboxylic acid, or an acid anhydride/a lower alkyl ester of the polycarboxylic acid), a urethane-based resin (such as a polyaddition product between a polyisocyanate and an active hydrogen group-containing compound (such as a diol, a polyol triol, a dicarboxylic acid, a polycarboxylic acid, a polyamine or a polythiol)), an epoxy-based resin (such as a ring-opening polymer of polyepoxide, or a polyaddition product of polyepoxide and the foregoing active hydrogen group-containing compound), and a copolymer between an α-olefin and a vinyl carboxylate, an acrylic acid ester, or another vinyl monomer.

Among these, an olefin-based resin (in particular, an ethylene-containing polymer) and a copolymer between an α-olefin and a vinyl carboxylate are particularly preferable. As the copolymer between an α-olefin and a vinyl carboxylate, ethylene-vinyl acetate copolymer (EVA) is particularly preferable. When EVA is used, an organic peroxide such as benzoyl peroxide, dicumyl peroxide, or 2,5-dimethyl-2,5-di(t-butylperoxy)hexane is preferably used as a cross-linking agent.

The sealing materials 14a and 14b may be constituted with the same material, or may be constituted with materials different from each other from the viewpoint of the compatibility between the temperature cycle resistance and the high-temperature and high-moisture resistance. Examples of the constituent materials of the sealing materials 14a and 14b and the combination of the constituent materials include a case where a resin having a high degree of cross-linking density is used for the sealing material 14a, and a resin having a low degree of cross-linking density or a non-cross-linked resin is used for the sealing material 14b. The cross-linking density of a resin can be evaluated from a gel fraction. The higher the gel fraction is, the higher the cross-linking density of the resin tends to be.

The coupling agent is included at least in the sealing material 14a, and is preferably also included in the sealing material 14b. By using the coupling agent, the adhesion strength between the solar cells 11 and the sealing material 14 is improved, and the suppression of the interface detachment is facilitated. Examples of the coupling agent include a silane coupling agent, a titanate-based coupling agent and an aluminate-based coupling agent. Among these, the silane coupling agent is particularly preferable. Examples of the silane coupling agent include vinyltriethoxysilane, γ-glycidoxypropyltrimethoxysilane, and γ-methacryloxypropyltrimethoxysilane.

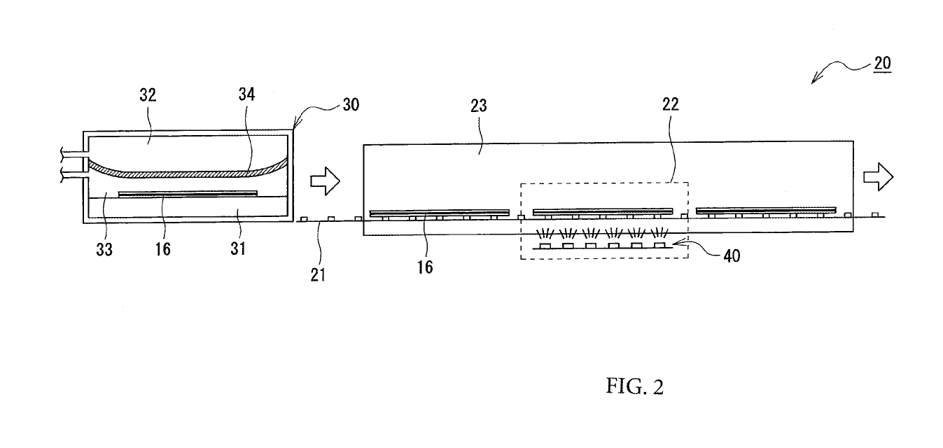

Hereinafter, by using FIG. 2 to FIG. 6, the solar cell module manufacturing device 20 as an example of the embodiments is described in detail.

FIG. 2 is a view showing the main part of a solar cell module manufacturing device 20.

The solar cell module manufacturing device 20 includes a laminating device 30 and a light source unit 40. The laminating device 30 is a device for preparing a laminated body 16 by superposing, and heating and pressure bonding, the solar cells 11, the sealing material 14, the first protection member 12, and the second protection member 13. The light source unit 40 is a device which irradiates the laminated body 16 with light to preferentially heat the solar cells 11 in the laminated body 16, and indirectly heats the sealing material 14 through the temperature increase of the solar cells 11. The solar cell module manufacturing device 20 further includes a belt conveyor 21 as a conveying unit of the laminated body 16, and a heating furnace 23 to heat the whole of the laminated body 16.

In the present embodiment, the laminated body 16 carried out from the laminating device 30 is carried into the heating furnace 23, and the laminated body 16 in the heating furnace 23 is irradiated with light. In other words, the light irradiation step is performed during the heat treatment step for heating the whole of the laminated body 16. As will be described later in detail, the light source unit 40 is preferably provided outside the heating furnace 23, and the light irradiation is performed through the translucent member 25 arranged in the heating furnace 23. It is to be noted that the heat treatment step and the light irradiation step may be performed separately. The heat treatment step and the light irradiation step may each be performed a plurality of times.

The belt conveyor 21 is a conveying device in which a plurality of bars, each having the laminated body 16 placed thereon, are arranged at predetermined intervals along the lengthwise direction of an endless belt. The belt conveyor 21 carries out the laminated body 16 prepared in the laminating device 30 from the laminating device 30, carries the laminated body 16 into the heating furnace 23, and carries the laminated body 16 to the light irradiation part 22, namely the light irradiation position with the light source unit 40. The conveying device for conveying the laminated body 16 is not limited to the belt conveyor 21, and may be, for example, a roller conveyor having a plurality of conveying rollers arranged therein.

In the heating furnace 23, for example, a heat treatment step (curing step) is performed in order to increase the cross-linking density by promoting the cross-linking reaction of the resin constituting the sealing material 14. The heating furnace 23 is not particularly limited as long as the heating furnace 23 allows the laminated body 16 to be carried and heat treated therein. As the heating furnace 23, for example, a resistance heating furnace, or a hot air circulation type heating furnace can be used. The temperature of the internal atmosphere of the heating furnace 23 is preferably approximately 100° C. to 180° C., and more preferably approximately 120° C. to 170° C. (for example, approximately 160° C.).

The laminating device 30 has a heater 31, and a vacuum chamber divided into two chambers (an upper vacuum chamber 32 and the lower vacuum chamber 33). The vacuum chamber is partitioned with a rubber sheet 34 having stretchability. The laminating device 30 forms the laminated body 16 by heating and pressure bonding the string of the solar cells 11, the sealing material sheets 14a and 14b, and the like disposed in a state of being superposed on each other on the heater 31. The structure of the laminating device 30 is not limited to the structure shown as an example, in FIG. 2.

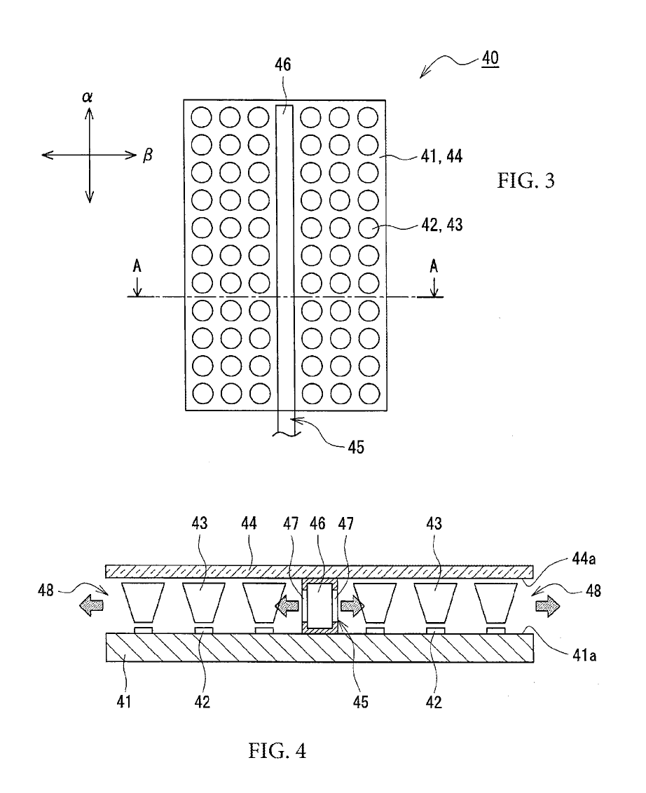

FIG. 3 is a plan view of the light source unit 40. FIG. 4 is a sectional view along the line AA in FIG. 3.

The light source unit 40 has a base material 41, a plurality of light sources 42 disposed on the base material 41, light collecting members 43 disposed in the optical paths of the light beams output from the light sources 42, and a translucent plate 44 disposed in the optical paths of the light beams outgoing from the light collecting members 43. The light source unit 40 has a structure in which the base material 41 and the translucent plate 44 are disposed so as to face each other, and the light sources 42 and the light collecting members 43 are sandwiched therebetween. The light source unit 40 further has a cooling device 45 allowing cooling air to flow in the horizontal direction along the main surface 44a of the translucent plate 44, between the base material 41 and the translucent plate 44. The cooling device 45 cools the constituent members of the light source unit 40 such as the light collecting members 43, and prevents the light collecting members 43 and the like from overheating.

The base material 41 is a member on which the light sources 42 are disposed. In the present embodiment, the plurality of the light sources 42 are disposed on the flat main surface 41a of the base material 41 so as to form an array of the light sources 42. The base material 41 is a plate-shaped member, and the main surface 41a thereof has an approximately rectangular shape in a planar view. Preferably, the base material 41 has a flow path of cooling water (coolant), and is cooled by using cooling water. The base material 41 is preferably constituted with a metal material having a high thermal conductivity, and the light sources 42 disposed in contact with the base material 41 are cooled mainly by the cooling water introduced into the base material 41. On the base material 41, for example, lead wires and connectors are also disposed, and these are also cooled by the cooling water. It is to be noted that the shape of the base material 41 is not limited to an approximately rectangular shape in a planar view, and may be an approximately square shape in a planar view.

The light sources 42 may be disposed irregularly on the main surface 41a of the base material 41, but are preferably regularly disposed along a first direction α and a second direction β of the base material 41. In the present description, the first direction means one direction along the main surface 41a of the base material 41, and the second direction means the direction perpendicular to the first direction and along the main surface 41a. Hereinafter, the first direction α is defined as “the long side direction α,” and the second direction β is defined as “the short side direction β,” and the terms, the long side direction α and the short side direction β, are sometimes used for the constituent elements other than the base material 41.

The light sources 42 are disposed more along the long side direction α than along the short side direction β, on the main surface 41a of the base material 41. In the example shown in FIG. 3, the intervals between the adjacent light sources 42 are approximately the same in both directions. The disposition of the light sources 42 at approximately the same intervals allows the laminated body 16 to be uniformly irradiated with light. The light sources 42 are disposed regularly and highly densely over the whole of the main surface 41a except for the portion at which an air duct 46 to be described later is provided. The shape in a planar view of the array of the light sources 42 corresponds to the shape of the main surface 41a and has an approximately rectangular shape in a planar view. The laminated body 16 generally has an approximately rectangular shape in a planar view, and accordingly, the use of the array having such a shape as described enables an efficient light irradiation.

The light sources 42 each output the light having a maximum peak wavelength of 1500 nm or less (hereinafter, sometimes referred to as “the specific light”). The maximum peak wavelength of the specific light is preferably approximately 400 nm to 1500 nm, and more preferably approximately 400 nm to 1200 nm, from the viewpoint of, for example, the selective heating of the solar cells 11 and the prevention of the degradation of the sealing material 14. The light having the maximum peak wavelength falling within the aforementioned range tends to be easily absorbed by the solar cells 11, and easily transmits the sealing material 14. Accordingly the temperature of the solar cells 11 can be preferentially increased.

Devices in which the light intensity (radiant intensity) of the light having wavelengths of 1500 nm or more of the output specific light is preferably 1% or less and more preferably 0.5% or less of the maximum peak intensity (maximum radiant intensity) are used for the light sources 42. In the specific light output from the light sources 42, the proportion of the light having wavelengths of 1200 nm or less is particularly preferably 99% or more. The light having wavelengths of more than 1200 nm, in particular, the light having wavelengths of more than 1500 nm is easily absorbed by the sealing material 14 (in particular, olefin resin), and accordingly, the specific light with which the laminated body 16 is irradiated preferably has a large proportion of the light having wavelengths of 1200 nm or less.

The light sources 42 may be any devices capable of irradiating the specific light such as xenon lamps and halogen lamps, and are preferably LEDs. For the light sources 42, for example, there are used LEDs, in each of which the radiant intensity of the light having wavelengths of 1500 nm or more of the output specific light is 1% or less, more preferably 0.5% or less, of the maximum radiant intensity. Examples of the preferable LED include an LED having a COB (Chip on Board) structure.

In the light source unit 40, preferably, light sources 42 (LEDs) being high in output power and being capable of performing continuous irradiation, are disposed highly densely on the base material 41. Thus, it is possible to secure a high light irradiation intensity to the laminated body 16. On the other hand, when the highly densely disposed LEDs are continuously used with high output power, the heat generation from the LEDs is large. In the present embodiment, the LEDs themselves are cooled by cooling water. However, for example, the light collecting members 43 and the translucent plate 44 are not directly disposed on the base material 41, and are exposed to high temperatures when the heat generated from the LEDs is large, and thus it is necessary to cool the light collecting members 43 and the translucent plate 44 using the cooling device 45.

The light collecting members 43 each have a function to collect the incident specific light on the laminated body 16. In order to allow the specific light output from the light sources 42 to be incident on the light collecting members 43 as much as possible, for example, the light collecting members 43 are preferably disposed in the vicinity of the light sources 42 by using supporting members (not shown) provided on the base material 41. However, when the light collecting members 43 are disposed in the vicinity of the light sources 42, the light collecting members 43 tend to be high in temperature. The light collecting members 43 can be reflector plates each having a metal high in light reflectance on the surface thereof, and the specific light is reflected, for collection, on the inside surfaces of the conical light collecting members 43. It is to be noted that as the light collecting members 43, for example, glass or resin lenses may also be used.

The light collecting members 43 may be provided in such a way that one light collecting member 43 is allotted to a unit of several light sources 42. However, the light collecting members 43 are preferably provided in such a way that one light collecting member 43 is allotted to one light source 42. In other words, one light collecting member 43 is provided on the optical path of the specific light output from each of the light sources 42, and thus there is formed an array of the light collecting members 43 corresponding to the array shape of the light sources 42. Similarly to the case of the light sources 42, the light collecting members 43 are regularly disposed both along the long side direction α and along the short side direction β in such a way that the intervals between the adjacent light collecting members 43 in the long side direction α are approximately the same as the intervals in the short side direction β.

The translucent plate 44 functions as a protection member of the light collecting members 43, and is provided so as to cover the whole of the light collecting members 43. The translucent plate 44 is a thin plate transmitting the specific light, and is disposed so as to face the main surface 41a of the base material 41. In the example shown in FIG. 4, the main surface 41a of the base material 41 is approximately parallel to the main surface 44a of the translucent plate 44. The translucent plate 44 is preferably constituted with a material having a high transmittance of the specific light and an excellent heat resistance. The translucent plate 44 is, for example, a glass plate (cover glass) having an approximately rectangular shape in a planar view.

The cooling device 45 allows cooling air to flow in the horizontal direction along the main surface 44a of the translucent plate 44 (the main surface 41a of the base material 41), between the base material 41 and the translucent plate 44 as described above, and mainly air-cools the members not directly disposed on the base material 41. By allowing cooling air to flow in the horizontal direction, the cooling air is free from collision and a turbulent flow is unlikely to occur, thus a smooth flow of air can be formed, and accordingly a stable cooling performance is obtained. The cooling air also hits the light sources 42, but the light sources 42 are cooled by the cooling water flowing in the base material 41, and accordingly the cooling device 45 mainly cools the constituent elements not disposed in contact with the base material 41 such as the light collecting members 43 and the translucent plate 44, and suppresses the temperature increases of the light collecting members 43 and the translucent plate 44.

The cooling device 45 is preferably constituted so as to allow the cooling air to flow in the short side direction β. Specifically, the cooling device 45 preferably allows the cooling air to flow in the direction in which the number of the light sources 42 constituting a line of the light sources 42 is small. In the present embodiment, the air duct 46 to allow cooling air to flow in the short side direction β is provided between the base material 41 and the translucent plate 44. The air duct 46 is a duct for blowing out the cooling air to both sides in the short side direction, and is provided in the central part in the short side direction of the base material 41, along the long side direction α. Exhaust openings 48 are provided at the positions opposite to the air duct 46 in the short side direction β. The exhaust openings 48 are provided at both ends in the short side direction of the base material 41, along the long side direction α. The cooling device 45 preferably has exhaust ducts (not shown), for example, at both ends in the short side direction of the light source unit 40, along the long side direction α. The exhaust ducts are ducts for sucking the cooling air, and the provision of the exhaust ducts at the positions of the exhaust openings 48 facilitates the flowing of the cooling air along the horizontal direction.

Air blowing openings 47, the blow-out openings for cooling air, are formed on both sides of the air duct 46, facing both sides in the short side direction. The cooling air being blown out from the air blowing openings 47 and flowing between the base material 41 and the translucent plate 44 flows in the short side direction β while cooling the light collecting members 43 and the like, and passes through the interspaces between the light collecting members 43 and the like, and is then discharged from the exhaust openings 48, at both ends in the short side direction of the base material 41. In this case, the discharged air amount of the cooling air from both ends in the long side direction is preferably regulated to be sufficiently smaller than the discharged air amount of the cooling air from the exhaust openings 48, for example, in such a way that the cooling air is not discharged from both ends in the long side direction of the base material 41. By disposing the air duct 46 in the central part in the short side direction, the flow path length of the cooling air flowing between the base material 41 and the translucent plate 44 is made shorter and the cooling efficiency is improved compared with, for example, the case where the cooling air is allowed to flow from one end toward the other end in the long side direction. In this case, the aforementioned flow path length is approximately half the length in the short side direction of the base material 41.

The air duct 46 is preferably provided across one end and the other end in the long side direction of the base material 41, namely, across approximately the whole length in the long side direction α, and the air blowing openings 47 are formed on the sides of the duct along the long side direction α. In this case, the exhaust openings 48 are also preferably provided across one end and the other end in the long side direction of the base material 41, namely, across approximately the whole length in the long side direction α. In the example shown in FIG. 3, for example, cooling air is introduced into the duct by a fan (not shown) from one end side of the air duct 46 in a lengthwise direction. However, cooling air may also be introduced from both lengthwise ends of the air duct 46. The air blowing openings 47 are preferably a plurality of openings formed along the lengthwise direction, and the opening areas of the air duct 46 may be constant, for example, along the long side direction α, or may be decreased towards one end side in the lengthwise direction. The width of the air duct 46 is preferably small within a range capable of ensuring the necessary air volume flow.

On the base material 41, approximately equal numbers of the light sources 42 are disposed respectively on both sides, in the short side direction, of the air duct 46. In other words, the air duct 46 is provided so as to intersect exactly the center of the array of the light sources 42. The numbers of the light sources 42 disposed on both sides, in the short side direction, of the air duct 46 are regulated so as to be approximately the same, and the air volume flows blown out from the air duct 46 to both sides in the short side direction are regulated so as to be approximately the same, and thus a uniform and stable cooling performance is obtained.

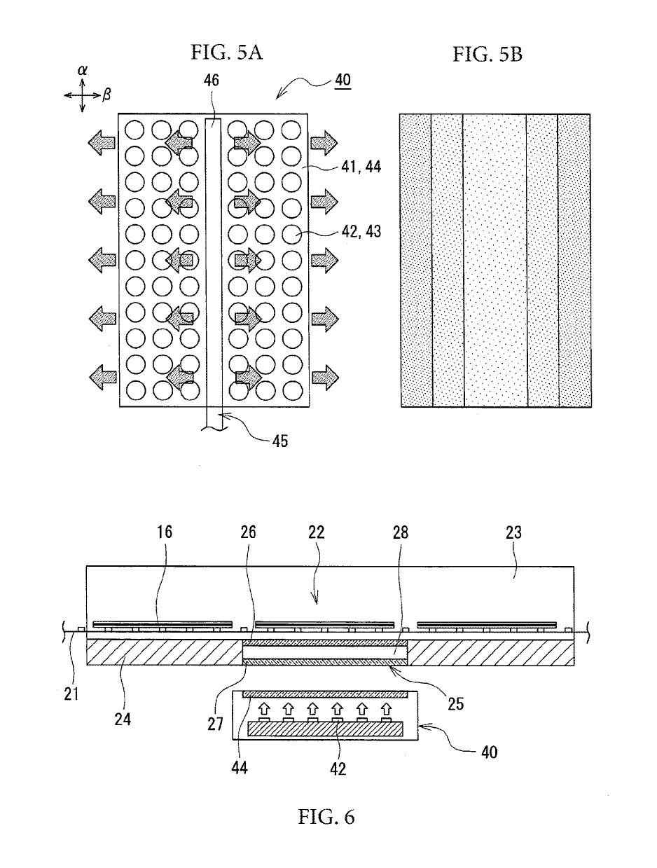

FIG. 5(A) is a view showing the flow of the cooling air and 5(B) a view showing the heat distribution.

As shown in FIG. 5(A), the cooling air blown out from the air duct 46 flows between the base material 41 and the translucent plate 44 along the short side direction β, and is discharged from between the base material 41 and the translucent plate 44, at both ends in the short side direction of the base material 41. The heat distribution shown in FIG. 5(B) is the result of the simulation of the temperature between the base material 41 and the translucent plate 44 under the conditions that the cooling air at 20 to 45° C. is allowed to flow at an air flow speed of 0.5 to 5.0 m/sec, and the higher the temperature in a region is, the larger the number of dots per unit area in the region is (the same also holds in FIG. 8 to FIG. 11). In the present embodiment, the cooling air blown out from the air duct 46 disposed in the central part in the short side direction flows toward both ends in the short side direction while cooling the light collecting members 43 and the like, and thus, the temperature of the cooling air is increased at both ends on the downstream side compared with the temperature of the cooling air in the central part, so as to increase the temperatures at both ends. However, the flow path length of the cooling air is short, as described above, and accordingly the degree of the temperature increase is small at both ends in the short side direction of the base material 41. In addition, the heat distribution is uniform along the long side direction α.

It is to be noted that as shown in FIG. 12, a cooling method is possible which blows out cooling air between the light sources 42 in the direction perpendicular to the base material 41. In the light source unit 100 shown in FIG. 12, there are provided a plurality of blow-out openings 101 of cooling air, penetrating through the base material 41 in the thickness direction. In this case, the cooling air is discharged, for example, from between the base material 41 and the translucent plate 44, in the whole periphery of the base material 41, and sometimes, the flow of the cooling air after blowing out is not uniform to cause disturbed flow and to create regions locally high in temperature. In other words, the cooling air is preferably allowed to flow in the horizontal direction in order to form a smooth flow of the cooling air by suppressing the generation of the disturbed flow.

FIG. 6 is a view showing the light irradiation part 22 (the heating furnace 23 and the light source unit 40).

The light source unit 40 irradiates the laminated body 16 in the heating furnace 23 with the specific light as described above. Accordingly, the translucent member 25 transmitting the specific light is fixed to at least part of the wall 24 of the heating furnace 23. The light source unit 40 is provided outside the heating furnace 23, and irradiates the laminated body 16 in the heating furnace 23 with the specific light through the translucent member 25. In the present embodiment, the translucent member 25 is provided in a larger area than the laminated body 16, in a part of the wall 24 constituting the bottom of the heating furnace 23. The light source unit 40 is provided below the translucent member 25 with a clearance between the light source unit 40 and the translucent member 25. The specific light incident into the heating furnace 23 through the translucent member 25 passes between the bars of the belt conveyor 21, and thus, the laminated body 16 is irradiated with the specific light.

The translucent member 25 may be constituted with a sheet of glass plate or three or more sheets of glass plates; however, in consideration of thermal insulation, the irradiation efficiency of the specific light and the like, the translucent member 25 is preferably constituted by laminating two sheets of glass plates 26 and 27. The glass plates 26 and 27 are arranged so as to face each other with a clearance 28 therebetween, and air or an inert gas is filled in the clearance 28, or the clearance 28 is in a vacuum state. Examples of the inert gas may include argon. The clearance 28 is formed and air or an inert gas is filled in the clearance 28 or the clearance 28 is allowed to be in a vacuum state, and thus the thermal insulation of the translucent member 25 is improved; consequently, the light source unit 40 disposed in the vicinity of the heating furnace 23 can be prevented from being high in temperature due to the effect of the heat of the heating furnace 23.

The thickness of each of the glass plates 26 and 27 is, for example, 1 mm to 10 mm, and the spacing between the glass plates 26 and 27 is, for example, 5 mm to 20 mm. For the glass plates 26 and 27, glass plates each having a high transmittance of the specific light are preferably used in the same manner as for the translucent plate 44. In order to suppress thermal radiation, a coating of a Low-E film such as a tin oxide film or a silver film may be made on each of the surfaces, on the sides of the light source unit 40, of the glass plates 26 and 27.

In the example shown in FIG. 6, the light source unit 40 is provided on the bottom side of the heating furnace 23, and light irradiation is performed from the bottom side to the laminated body 16; however, alternatively, the light source unit 40 may be provided on the upper side of the heating furnace 23, and light irradiation may be performed from the upper side to the laminated body 16. The irradiation of the specific light may be performed either on the light receiving surface side or on the rear surface side of the laminated body 16, or on both surfaces; for example, in the case of the laminated body 16 in which the incidence of the light from the rear surface side is difficult, the irradiation of the specific light is performed from the light receiving surface side (the side of the first protection member 12).

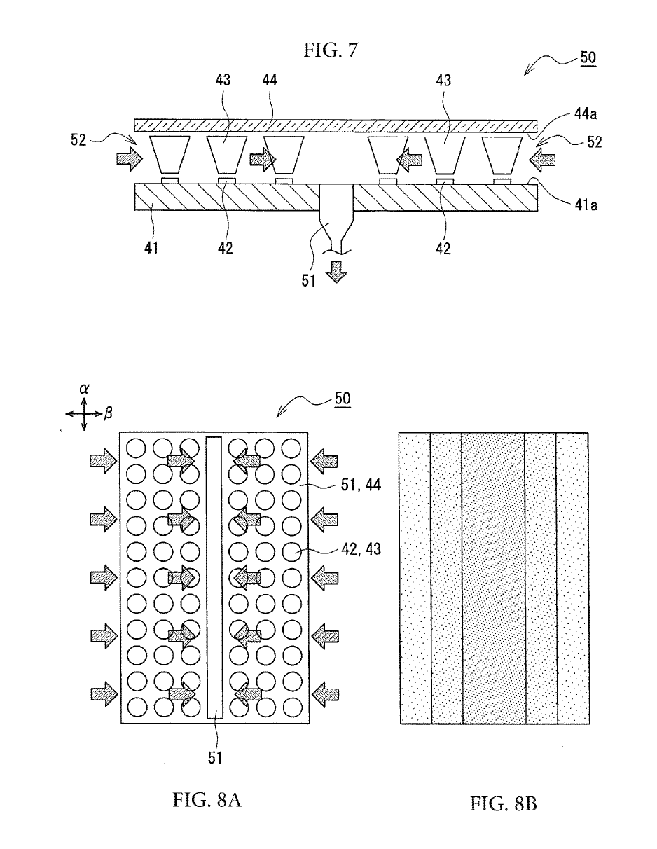

Here, FIG. 7 to FIG. 11 show the light source unit as another example of the embodiment.

In the light source unit 50 shown as an example in FIG. 7, an exhaust duct 51 is provided in place of the air duct 46. The exhaust duct 51 is the duct for sucking the cooling air, and is provided in the central part in the short side direction of the base material 41 along the long side direction α, in the same manner as in the case of the air duct 46. The exhaust duct 51 sucks the cooling air mainly from the vent holes 52 on both sides in the short side direction of the base material 41, and generates cooling air in the horizontal direction along the main surfaces 41a and 44a, between the base material 41 and the translucent plate 44. The width of the exhaust duct 51 is preferably as small as possible within a range allowing the necessary air volume flow to be secured. In the light source unit 50, approximately equal numbers of the light sources 42 are disposed respectively on the base material 41 on both sides, in the short side direction, of the exhaust duct 51, in the same manner as in the case of the light source unit 40.

As shown in FIG. 8, the cooling air, introduced by the exhaust duct 51 into between the base material 41 and the translucent plate 44 from both sides in the short side direction of the base material 41, flows between the base material 41 and the translucent plate 44, along the short side direction β, and is sucked into the exhaust duct 51 in the central part in the short side direction. In the light source unit 50, the flow of the cooling air is opposite to the flow of the cooling air in the case of the light source unit 40, and accordingly the temperature of the cooling air is increased in the central part in the short side direction of the base material 41, situated on the downstream sides, compared with both ends in the short side direction of the base material 41, and consequently the temperature is increased in the central part in the short side direction. However, the flow path length of the cooling air is short, as described above, and accordingly the degree of the temperature increase is small even in the central part in the short side direction. In addition, the heat distribution is uniform along the long side direction α.

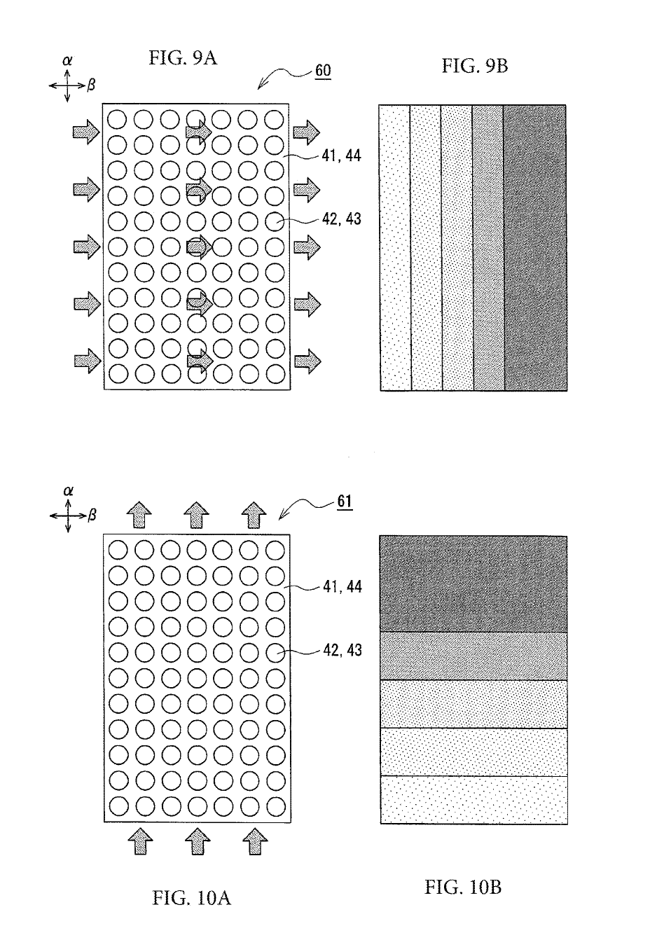

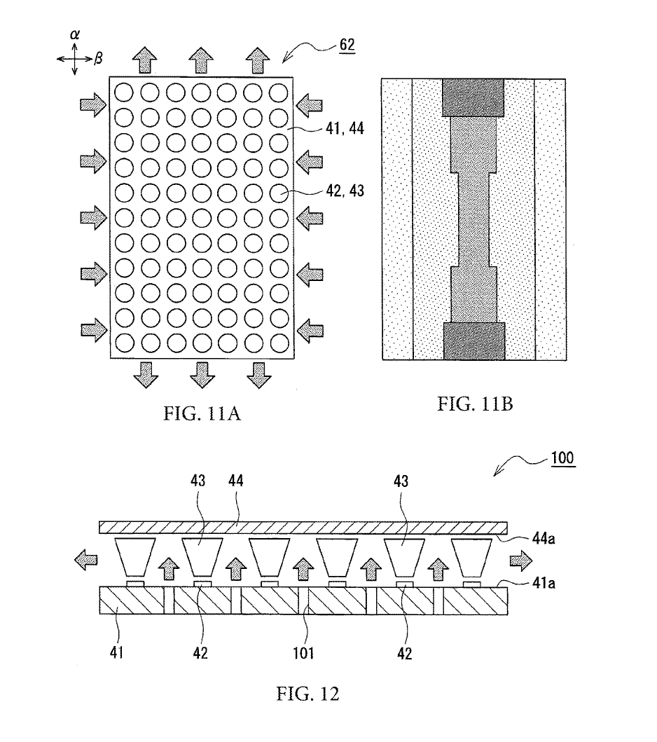

The light source units 60, 61 and 62 shown as examples in FIG. 9 to FIG. 11 are constituted in such a way that the cooling air flows along the horizontal direction, but are different from the light source units 40 and 50 in that a duct is not provided so as to intersect the array of the light sources 42 in between the base material 41 and the translucent plate 44. In this case, there is an advantage that the number of the light sources 42 capable of being disposed on the base material 41 is increased. On the other hand, the light source unit 60 shown as an example in FIG. 9 is constituted in such a way that the cooling air is allowed to flow from one end to the other end in the short side direction of the base material 41. The light source unit 61 shown as an example in FIG. 10 is constituted in such a way that the cooling air is allowed to flow from one end to the other end in the long side direction of the base material 41. Accordingly, in either case, compared with the light source units 40 and 50, the flow path length of the cooling air flowing between the base material 41 and the translucent plate 44 is longer, and the temperature increase is larger on the downstream side. The light source unit 62 shown as an example in FIG. 11 is constituted in such a way that the cooling air is introduced from both sides in the short side direction of the base material 41, and the cooling air is discharged from both sides in the long side direction of the base material 41. In this case, the flow path length is shorter compared with the light source units 60 and 61, and consequently the range in which the temperature increase is large is narrow, but the temperatures at both ends in the long side direction of the base material 41 are higher compared with the light source units 40 and 50.

Hereinafter, a manufacturing method of a solar cell module 10 using a solar cell module manufacturing device 20 is described in detail.

The manufacturing process of the solar cell module 10 includes a first step of preparing a laminated body 16 by superposing, heating and pressure bonding (laminating) a string of the solar cells 11, a first protection member 12, a second protection member 13, and sheet-shaped sealing materials 14a and 14b. The first step is referred to as a laminating step. The string of solar cells 11 can be prepared by a heretofore known method. The manufacturing process of the solar cell module 10 includes a second step of indirectly heating the sealing material 14 through the temperature increase of the solar cells 11 caused by irradiating the laminated body 16 prepared in the first step with the specific light to preferentially heat the solar cells 11 of the laminated body 16.

The first step is performed by using the laminating device 30. In the first step, the first protection member 12, the sealing material sheet 14a, the solar cells 11, the sealing material sheet 14b, and the second protection member 13 are disposed in this order in a state of being superposed on each other on the heater 31. Successively, the superposed respective members are heated with the heater 31 while the upper vacuum chamber 32 and the lower vacuum chamber 33 are being evacuated. Next, the evacuation of the upper vacuum chamber 32 is ceased and the air is introduced into the upper vacuum chamber 32, and thus, the rubber sheet 34 is extended toward the heater 31 to pressurize the laminated product. The laminated product in this state is heated to approximately 150° C., and thus the resins constituting the sealing material sheets 14a and 14b are softened (melted). In addition, when the aforementioned resins are cross-linkable resins, the heating allows the cross-linking reaction to proceed.

The manufacturing process of a solar cell module 10 preferably includes a heat treatment step of heating the whole of the laminated body 16 prepared in the first step. The heat treatment step is performed by using the heating furnace 23. In the present embodiment, the second step (the light irradiation step) is performed during the heat treatment step. Specifically, the laminated body 16 prepared in the first step is carried into the heating furnace 23, and the heat treatment step and the light irradiation step are performed simultaneously in the heating furnace 23. The heat treatment step is a step of increasing the cross-linking density by promoting the cross-linking reaction of the resins constituting the sealing material 14 as described above. For example, the atmospheric temperature inside the heating furnace 23 is 100° C. to 180° C., and the treatment time is 5 minutes to 60 minutes.

The second step is a light-irradiation annealing step of irradiating the laminated body 16 with light and preferentially heating the solar cells 11. Preferentially heating the solar cells 11 means heating so as to preferentially increase the temperature of the solar cells 11 more than the temperatures of the other members in the laminated body 16. In the second step, by preferentially heating the solar cells 11, the sealing material 14 is indirectly heated through the temperature increase of the solar cell 11. In the second step, the heat of the heated solar cells 11 is transferred to the sealing material 14, and for example, the sealing material 14 is locally heated in the vicinity of the interface with the solar cells 11. In other words, the second step selectively heats only the solar cells 11, and does not directly increase the temperature of the sealing material 14, or directly increases the temperature of the sealing material 14 to only a smaller degree. Such a local heating of the sealing material 14 allows the adhesion strength between the solar cells 11 and the sealing material 14 to be improved while preventing the generation of bubbles in the sealing material 14. The present step is particularly preferable in the case where the sealing material 14 contains a coupling agent.

In the second step, the light source unit 40 irradiates the laminated body 16 with the specific light having a maximum peak wavelength of 1500 nm or less. The laminated body 16 is heated wholly by the heating furnace 23. However, the irradiation with the specific light increases the temperature of the solar cells 11 and the temperature of the sealing material 14 in the vicinity of the interface with the solar cells 11, so as to be, for example, approximately 2° C. to 70° C. higher than the temperatures of the other portions of the laminated body 16. It is to be noted that the temperature of the sealing material 14 in the vicinity of the interface with the solar cells 11 is preferably 200° C. or lower. The heating temperature of the solar cells 11 can be regulated by varying, for example, the output power of the light sources 42 and the light irradiation time. The light irradiation time is, for example, 1 to 30 minutes.

In the second step, the laminated bodies 16 are continuously carried in the light irradiation part 22, and the light source unit 40 preferably continuously irradiates the laminated bodies with the specific light while the cooling air is cooling at least the light collecting members 43 and the translucent plate 44. In other words, the light sources 42 are not turned off every time the laminated body 16 is treated. Additionally, the cooling device 45 preferably continuously supplies cooling air while the light sources 42 are turned on. The cooling device 45 cools the light collecting members 43 and the like, and thus, the temperature increases of the light collecting members 43 and the like is suppressed to enable the continuous irradiation with the specific light. The light sources 42 are mainly cooled by the cooling water supplied to the base material 41. It is to be noted that the continuous conveying of laminated bodies 16 is sometimes temporarily stopped because of the conditions of the other steps. In such a case, preferably, the light sources 42 are turned off while the conveying is temporarily stopped, and the light sources 42 are again turned on when the conveying is started again.

After the completion of the above-described steps, if necessary, by passing through a trimming step of the laminated body 16, and steps of attaching frames and terminal boxes, the solar cell module 10 is obtained.

As described above, the solar cell module manufacturing device 20 can continuously perform a high intensity light irradiation because the cooling device 45 efficiently cools the light collecting members 43, the translucent plate 44 and the like. Accordingly, the use of the aforementioned device improves the productivity of the solar cell module 10.

### REFERENCE SIGNS LIST

10 solar cell module, 11 solar cell, 12 first protection member, 13 second protection member, 14 sealing material, 14a first sealing material, 14b second sealing material, 15 conductive wire, 16 laminated body, 20 solar cell module manufacturing device, 21 belt conveyor, 22 light irradiation part, 23 heating furnace, 24 wall, 25 translucent member, 26, 27 glass plate, 28 clearance, 30 laminating device, 31 heater, 32 upper vacuum chamber, 33 lower vacuum chamber, 34 rubber sheet, 40, 50, 60, 61, 62 light source unit, 41 base material, 41a, 44a main surface, 42 light source, 43 light collecting member, 44 translucent plate, 45 cooling device, 46 air duct, 47 air blowing opening, 48 exhaust opening, 51 exhaust duct

1. A solar cell module manufacturing device comprising:
a laminating device for preparing a laminated body by superposing, heating and pressure bonding solar cells, sealing materials and protection members; and
a light source unit irradiating the laminated body with light to preferentially heat the solar cells and thus indirectly heat the sealing materials through the temperature increase of the solar cells,
wherein the light source unit includes:
a base material;
a plurality of light sources disposed on the base material and each outputting light having a maximum peak wavelength of 1500 nm or less;
light collecting members disposed on the optical paths of the light beams output from the light sources and collecting the aforementioned light beams;
a translucent plate disposed on the optical paths of the light beams emitted from the light collecting members; and
a cooling device allowing cooling air to flow in the horizontal direction along the main surface of the translucent plate, between the base material and the translucent plate.

2. The solar cell module manufacturing device according to claim 1,
wherein the light sources are disposed more along a second direction perpendicular to a first direction of the base material than along the first direction of the base material; and
the cooling device is constituted so as to allow the cooling air to flow in the first direction.

3. The solar cell module manufacturing device according to claim 2,
wherein the cooling device has a duct for allowing the cooling air to flow in the first direction; and
the duct is provided along the second direction.

4. The solar cell module manufacturing device according to claim 3, wherein approximately equal numbers of the light sources are disposed respectively on both sides, in the first direction, of the duct on the base material.

5. The solar cell module manufacturing device according to claim 4, wherein the duct is an air duct for blowing out the cooling air toward both sides in the first direction.

6. The solar cell module manufacturing device according to claim 5, further comprising exhaust openings provided at positions opposite to the air duct in the first direction, along the second direction,
wherein the discharged air amount at the ends of the base material in the second direction is smaller than the discharged air amount at the exhaust openings.

7. The solar cell module manufacturing device according to claim 1, wherein the light sources are LEDs in each of which intensity of the light having wavelengths of 1500 nm or more of the light is 1% or less of the maximum peak.

8. The solar cell module manufacturing device according to claim 1, wherein the base material has a flow path of cooling water, and is cooled by using cooling water.

9. The solar cell module manufacturing device according to claim 1, comprising:
a heating furnace for heating the whole of the laminated body,
wherein a translucent member constituted by laminating a plurality of glass plates is fixed to at least part of the wall of the heating furnace; and
the light source unit is provided outside the heating furnace, and the laminated body in the heating furnace is irradiated with the light through the translucent member.

10. The solar cell module manufacturing device according to claim 9,
wherein the glass plates constituting the translucent member are arranged so as to face each other with clearances therebetween; and
air or an inert gas is filled in the clearances, or the clearances are each in a vacuum state.

11. A solar cell module manufacturing method using the manufacturing device according to claim 1, comprising:
a first step of preparing a laminated body by superposing, and heating and pressure bonding, solar cells, sealing materials and protection members; and
a second step of indirectly heating the sealing materials through the temperature increase of the solar cells caused by irradiating the laminated body with light to preferentially heat the solar cells of the laminated body.

12. The solar cell module manufacturing method according to claim 11,
wherein in the second step, the laminated bodies are continuously carried to the light irradiation position with the light source unit; and
the light source unit continuously irradiates the laminated bodies with the light while the cooling air is cooling at least the light collecting members and the translucent plate.
